(19) United States
(12) Patent Application Publication
(10) Pub. No.: US 2014/0001932 A1
(43) Pub. Date: Jan. 2, 2014

(54) Modular Outdoor Enclosure and Gravity Damper System

(71) Applicants: Nathan L. Westby, Zimmerman, MN (US); Trent T. Jones, White Bear Lake, MN (US); William J. Nepsha, Zimmerman, MN (US); Jamie M. Livgard, Big Lake, MN (US)

(72) Inventors: Nathan L. Westby, Zimmerman, MN (US); Trent T. Jones, White Bear Lake, MN (US); William J. Nepsha, Zimmerman, MN (US); Jamie M. Livgard, Big Lake, MN (US)

(21) Appl. No.: 13/538,816

(22) Filed: Jun. 29, 2012

(51) Int. Cl. H05K 5/03; H05K 5/00; B23P 11/00

(52) U.S. Cl. 312/223.1; 29/428; 454/184

(57) ABSTRACT

A modular, ventilated enclosure includes a base and a frame coupled to the base. The base includes at least one mounting receptacle for mounting a fan. The enclosure can include four side panels coupled to the frame and a back panel coupled to the frame in the interior of the enclosure. The back panel can be adapted to mount electrical equipment. A cover can be coupled to the frame and can include an overhang to prevent debris from entering the interior of the enclosure. The enclosure can also include a gravity controlled damper system with a damper that moves to an open position when an internal pressure in the interior of the enclosure increases. The enclosure can include a passive air flow passage that ventilates the enclosure when the damper is in the closed position.

### BACKGROUND

Electrical enclosures can be used to house a variety of electronic equipment in a variety of environments. In outdoor environments, electrical enclosures are used to house electrical equipment for agricultural applications, such as large drives for irrigation pumps and sprinkler systems. This electrical equipment is cumbersome, heavy, and often is housed in the enclosure in a remote environment, such as near the edge of the agricultural field that the equipment is serving. Furthermore, the electrical equipment may be damaged if it overheats due to a lack of proper cooling. Any ventilation provided in the electrical enclosure can lead to other potential problems for the electrical equipment such as damage from blowing snow or rain. Debris blowing in the wind and small animals can also present problems for the electrical equipment housed within the enclosure by entering the enclosure through any ventilation passages.

### SUMMARY OF THE INVENTION

Thus, it would be beneficial to provide an enclosure that can be constructed to support the electrical equipment and be of a modular design to be assembled on location. It would also be beneficial to provide an enclosure that uses a selective ventilation system that protects the internal components of the enclosure from the outside elements, yet allows proper cooling of the interior of the enclosure when necessary.

Some embodiments of the invention provide a modular enclosure for electrical equipment including a first side, a second side, a third side, a fourth side, and an interior. The modular enclosure can include a base including at least one mounting receptacle for mounting a first fan and a frame coupled to the base. The modular enclosure can also include a first side panel, a second side panel, a third side panel, and a fourth side panel coupled to the frame. The enclosure can include a cover coupled to the frame that includes an overhang to prevent debris from entering the interior of the enclosure. The enclosure can also include a first gravity controlled damper. The first gravity controlled damper can move to an open position when an internal pressure in the interior of the enclosure increases and moving to a closed position when the internal pressure in the interior of the enclosure decreases. The enclosure can further include a passive air flow passage that can ventilate the interior of the enclosure when the first gravity controlled damper is in the closed position.

Another embodiment of the invention provides method of assembling a ventilated modular enclosure with electrical equipment generating heat. The method can include providing a modular enclosure that includes a base, a frame, side panels, a cover, and a back panel. The method can include installing the base in a desired location. The method can also include placing the back panel of the enclosure in a horizontal orientation with respect to the ground. Furthermore, the method can include installing the electrical equipment on the back panel while the back panel is in the horizontal orientation. Additionally, the method can include coupling the frame to the back panel and lifting the frame and the back panel to a vertical orientation. The method can further include coupling the side panels and cover to the frame and coupling the base to the frame.

Another aspect of the invention provides for a method of ventilating an enclosure. The method can include providing a gravity controlled damper system that includes a first damper. The first damper can prevent debris from entering the outdoor enclosure when the first damper is in a closed position. The first damper can ventilate the enclosure when the first damper is in an open position. The method can also include coupling the first damper to the enclosure and sensing a temperature in the interior of the enclosure. The method can include providing a passive air flow passage to the enclosure. The passive air flow passage can ventilate the enclosure when the first damper is in the closed position. The method can include activating a fan when the temperature in the interior of the enclosure is above a threshold temperature. The fan can increase an internal pressure in the enclosure and move the first damper to the open position.

These and other features, aspects, and advantages of the present invention will become better understood upon consideration of the following detailed description, drawings, and appended claims.

### DESCRIPTION OF THE DRAWINGS

FIG. 1 is a front perspective view of an enclosure according to one embodiment of the invention including a base, frame, side panels, and cover.

FIG. 2 is an exploded perspective view of the enclosure of FIG. 1.

FIG. 3 is an exploded perspective view of a frame being assembled with a back panel resting on stands.

FIG. 4 is a cross-sectional perspective view taken along line 4-4 in FIG. 1.

FIG. 5 is a cross-sectional front elevational view taken along line 4-4 in FIG.

FIG. 6 is a detailed view taken along line 6-6 from FIG. 5.

FIG. 7 is a cross-sectional view taken along line 7-7 from FIG. 1.

FIG. 8 is a detailed view taken along line 8-8 from FIG. 7.

FIG. 9 is a flow chart illustrating a method of ventilating an enclosure.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The following discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown, but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

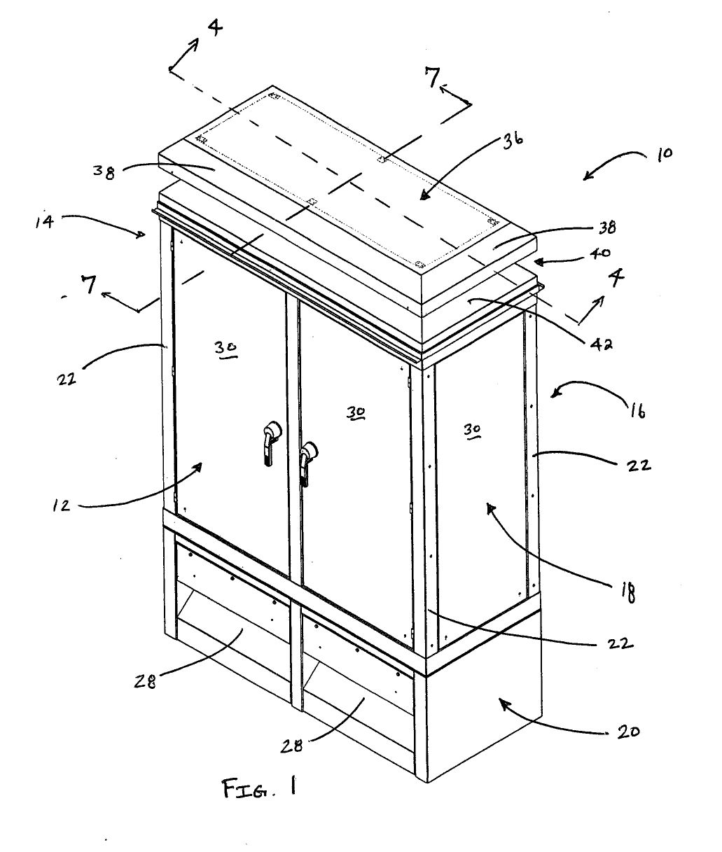

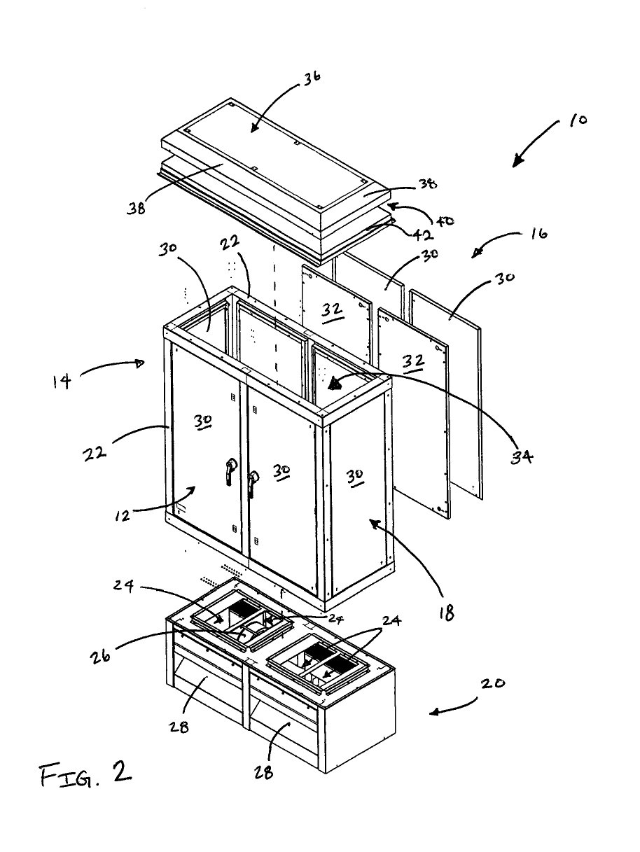

FIGS. 1 and 2 illustrate a modular enclosure 10 according to one embodiment of the invention. The enclosure 10 can include a first side 12, a second side 14, a third side 16, and a fourth side 18. As shown in FIG. 2, the modular enclosure 10 can include a base 20 and a frame 22 coupled to the base 20. The base 20 can include mounting receptacles 24 that are adapted to receive modular impeller fans 26 (a single fan is shown in FIG. 2). The fans 26 can be powered by an external power source (not shown), located, for example, under the base 20 in a concrete footing. Depending on the necessary amount of air flow needed in the enclosure for cooling purposes (which a user can calculate based on the equipment housed within the enclosure 10 and the environment the enclosure 10 will be placed in), one or more fans 26 can be mounted in the receptacles 24 to reach the cubic feet per minute rate of flow desired. The base 20 can include louvers 28 through which air flows into the enclosure 10, as will be discussed in more detail below.

The modular enclosure 10 can also include side panels 30 that are coupled to the frame 22. The side panels 30 can be flush with the frame 22. Six side panels 30 are shown in FIGS. 1 and 2. Two side panels 30 that form doors for the enclosure 10 are on the first side 12 of the enclosure 10 and two side panels 30 are on the third side 16 of the enclosure 10. One side panel 30 is on the second side 14 and one side panel 30 is on the fourth side 18 of the enclosure 10. The enclosure 10 can include various other numbers of side panels 30 on the sides 12, 14, 16, 18. In one embodiment, the side panels 30 and the frame 22 can be constructed of aluminum.

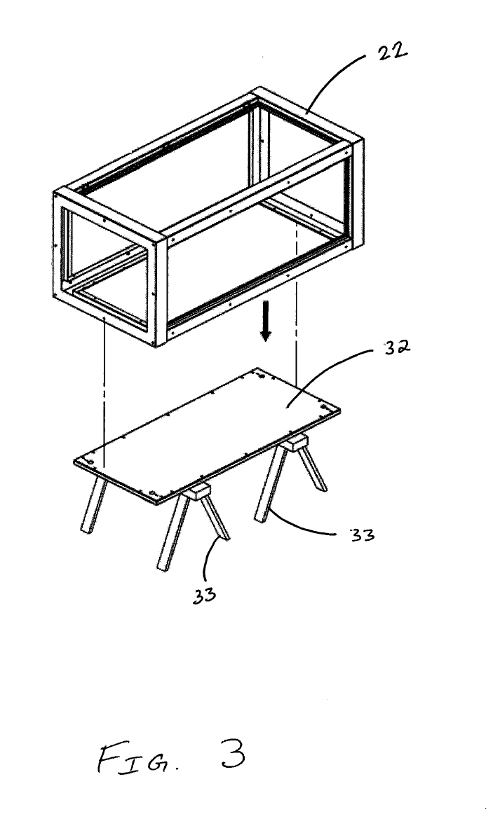

The enclosure 10 can also include a back panel 32 (two back panels are shown in FIG. 2). The back panel 32 can be adapted for mounting electrical equipment (not shown), such as drives for pumps and other agricultural equipment. In one embodiment, the back panel 32 can be constructed of steel and can weigh up to about 2000 pounds when populated with electrical equipment. When setting up the enclosure 10, the electrical equipment can be populated on to the back panel 32 on location with the back panel 32 resting on stands 33, as shown in FIG. 3. After populating the back panel 32 with electrical equipment, the frame 22 can be lowered on to the back panel 32 and the back panel 32 can then be coupled to the frame 22, such that the back panel 32 (and the electrical equipment) is in the interior 34 of the enclosure 10. The process of mounting electrical equipment to the back panel 32 when the back panel 32 is resting in a horizontal orientation on stands 33 can allow for increased ease in installation of the electrical equipment to the enclosure 10 and for more efficient installations. As noted above, in one embodiment the frame 22 can be constructed of aluminum, which provides reduced weight and assists in the assembly of the enclosure 10. After coupling the frame 22 and the back panel 32, the frame 22 and back panel 32 can be lifted to a vertical orientation. The frame 22 can be coupled to the base 20 of the enclosure 10 and the side panels 30 can be coupled to the frame 22 either before or after the frame 22 is coupled to the base 20.

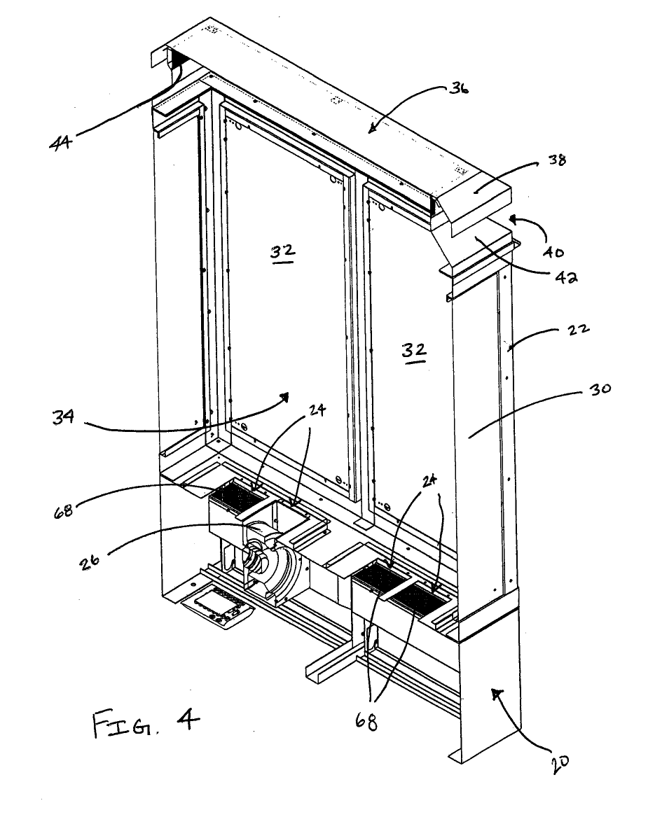

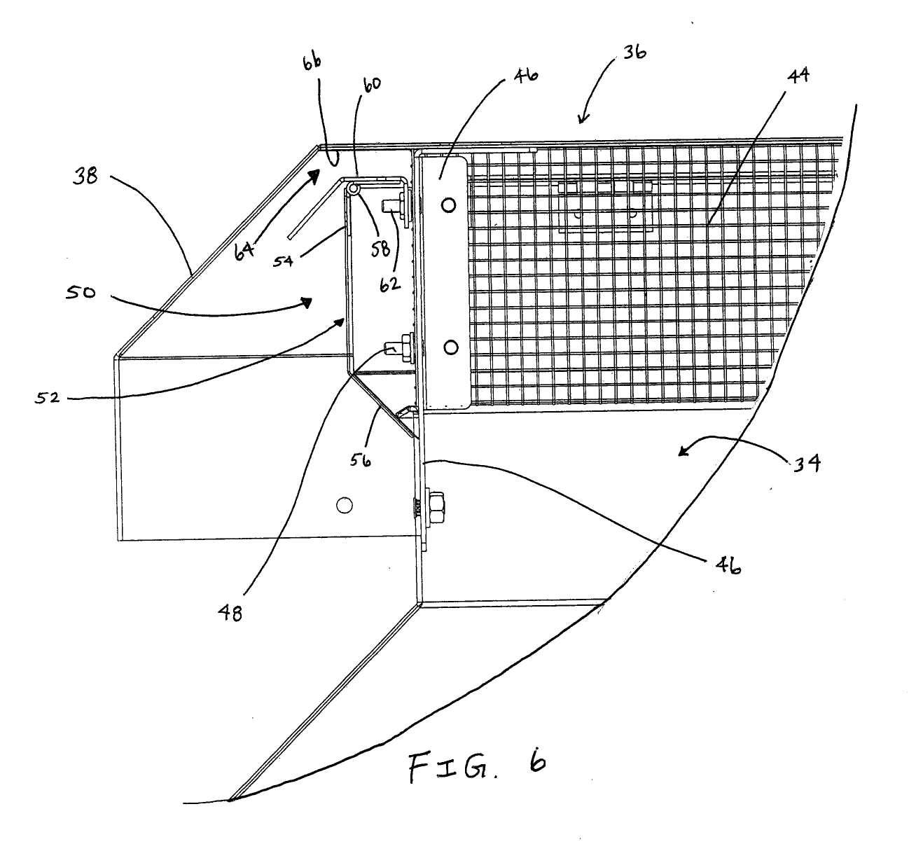

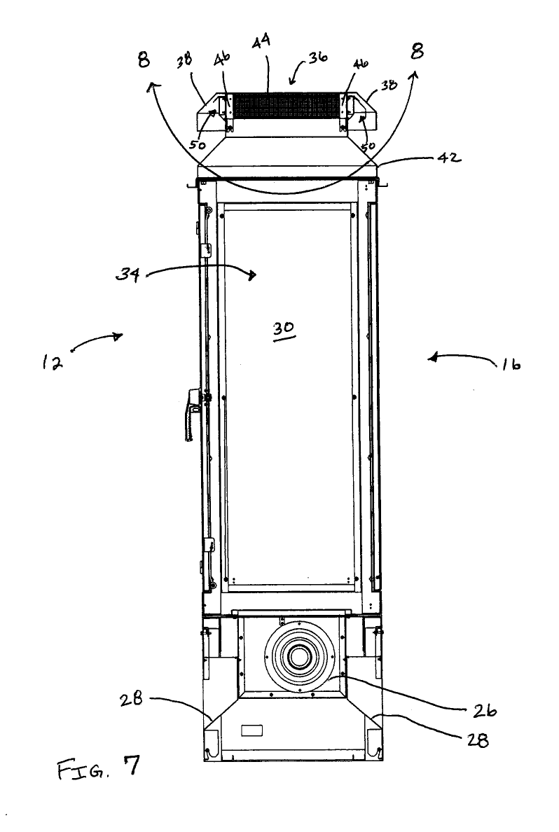

The modular enclosure 10 can also include a cover 36 that is coupled to the frame 22. The cover 36 can include an overhang 38 that extends around all four sides 12, 14, 16, 18 of the enclosure 10. A gap 40 can be located between the overhang 38 and a portion 42 of the cover 36 coupled to the frame 22. The cover 36 can prevent debris, such as sand, dust, precipitation, and other foreign objects, from entering the interior 34 of the enclosure 10. As shown in FIGS. 4-7, the cover 36 can include an internal mesh screen 44. The internal mesh screen 44 can be used as a way to further prevent debris from entering the interior 34 of the enclosure 10, yet allow air to circulate in and out of the enclosure 10. The internal mesh screen 44 can extend around all four sides 12, 14, 16, 18 of the enclosure 10. The internal mesh screen 44 can be coupled to the cover 36 with the use of mounting studs 46 and fasteners 48, as shown in FIG. 6.

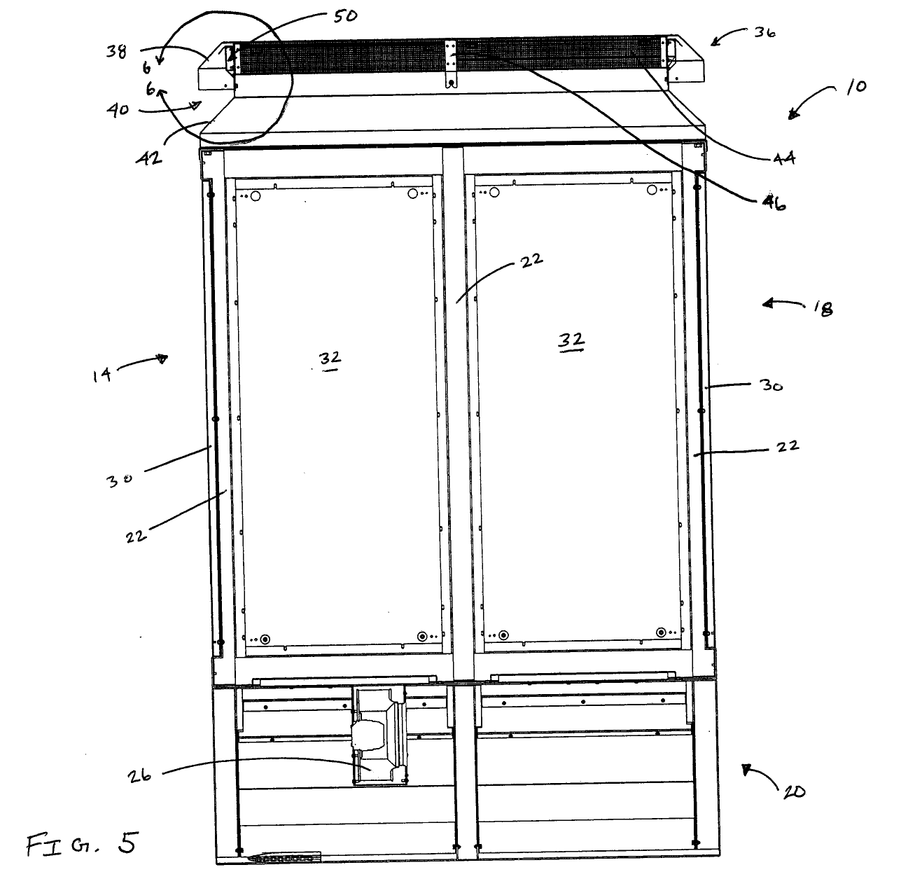

As shown in FIGS. 5-8, the enclosure 10 can include a gravity controlled damper system 50. The gravity controlled damper system 50 can include gravity controlled dampers 52. The gravity controlled dampers 52 can each include a proximal end 54 and a distal end 56. The proximal end 54 can be coupled to a hinge 58. The hinge 58 can be coupled to a hood 60. The hood 60 can be coupled to the cover 36 with mounting studs 46 and fasteners 62. The enclosure 10 can have one or more gravity controlled dampers 52, and in one embodiment, four dampers 52 are shown with one on each side 12, 14, 16, 18.

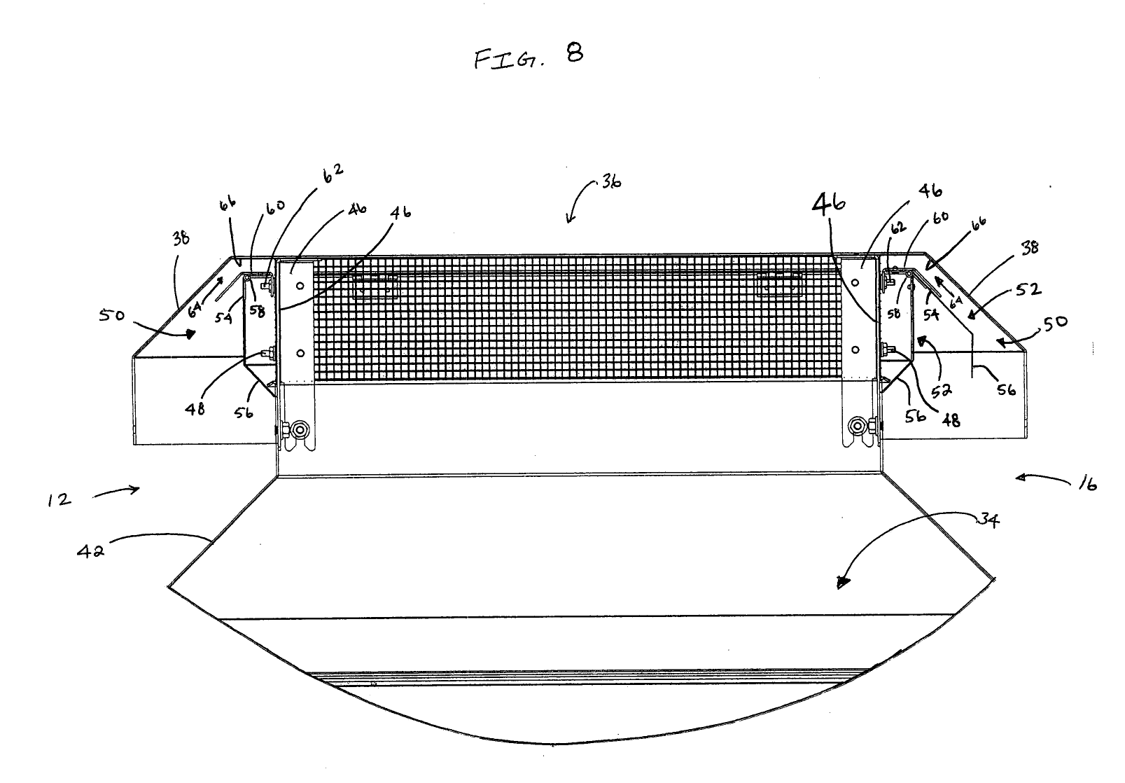

The gravity controlled dampers 52 can move between a closed position and an open position. A gravity controlled damper 52 in the closed position is shown in detail in FIG. 6. In the closed position, the gravity controlled damper 52 prevents debris from entering the interior 34 of the enclosure 10. A gravity controlled damper 52 in the open position is shown in detail on the third side 16 of the enclosure 10 in FIG. 8. In the embodiment of the enclosure 10 shown in FIGS. 1-8, the enclosure 10 includes two gravity controlled dampers on both the first side 12 and the third side 16 of the enclosure 10. The third side 16 of the enclosure 10 has one gravity controlled damper 52 in the open position and one gravity controlled damper 52 in the closed position. In the open position, the gravity controlled damper 52 provides for increased ventilation of the interior 34 of the enclosure 10, which can decrease the temperature in the interior 34 of the enclosure 10. Increasing the ventilation of the enclosure 10 can help cool the electrical equipment mounted within the enclosure 10. As shown in FIG. 8, the hood 60 can define the degree that the gravity controlled damper 52 can rotate about the hinge 58.

The gravity controlled dampers 52 can move from a closed position to an open position when the internal pressure in the interior 34 of the enclosure 34 increases. In one embodiment, the internal pressure in the interior 34 of the enclosure 34 can increase when the fan 26 is activated. Activation of the fan 26 can cause air flow through the interior 34 of the enclosure 10. Likewise, the gravity controlled damper 52 can move from an open position to a closed position when the internal pressure in the interior 34 of the enclosure 34 decreases. The internal pressure in the interior 34 of the enclosure 34 can decrease by deactivating the fan 26 in the enclosure 10.

The enclosure 10 can be ventilated even when the gravity controlled dampers 52 are in the closed position. The louvers 28 on the base 20 of the enclosure can include an internal mesh screen 68, as best shown in FIG. 4. The internal mesh screen 68 in the louvers 28 can provide for some passive air flow into the interior 34 of the enclosure 10. As shown in FIGS. 6 and 8, the cover 36 can also include a passive air flow passage 64. The passive air flow passage 64 can be defined by the passage between the hood 60 and an internal surface 66 of the cover 36. The passive air flow passage 64 can provide both an air intake port and an air exhaust port for the enclosure 10. Air can flow through the passive air flow passage 64 and through the internal mesh screen 44 into the interior 34 of the enclosure 10 as well as from the interior 34 of the enclosure 10 through the mesh screen 44 and out of the passive air flow passage 64. The passive air flow passage 64 can provide some ventilation to the enclosure 10 when the gravity controlled dampers 52 are in the closed position, but less ventilation for the enclosure 10 as compared to when the gravity controlled dampers 52 are in the open position. Additionally, in an embodiment that includes a louver 28 and a passive air flow passage 64, the enclosure 10 can have increased circulation and ventilation of air yet still be protected from debris entering into the interior 34 of the enclosure 10. In such a configuration, the louver 28 can provide an air intake port and the passive air flow passage 64 can provide an air exhaust port, and vice versa.

The fans 26 mounted in the receptacles 24 in the base 20 of the enclosure 10 can be impeller fans, such as a 250 mm impeller fan produced by McLean Midwest. The fans 26 can be in electrical communication with a thermostat (not shown), thermocouple, or temperature sensor that can activate and/or deactivate the fans 26.

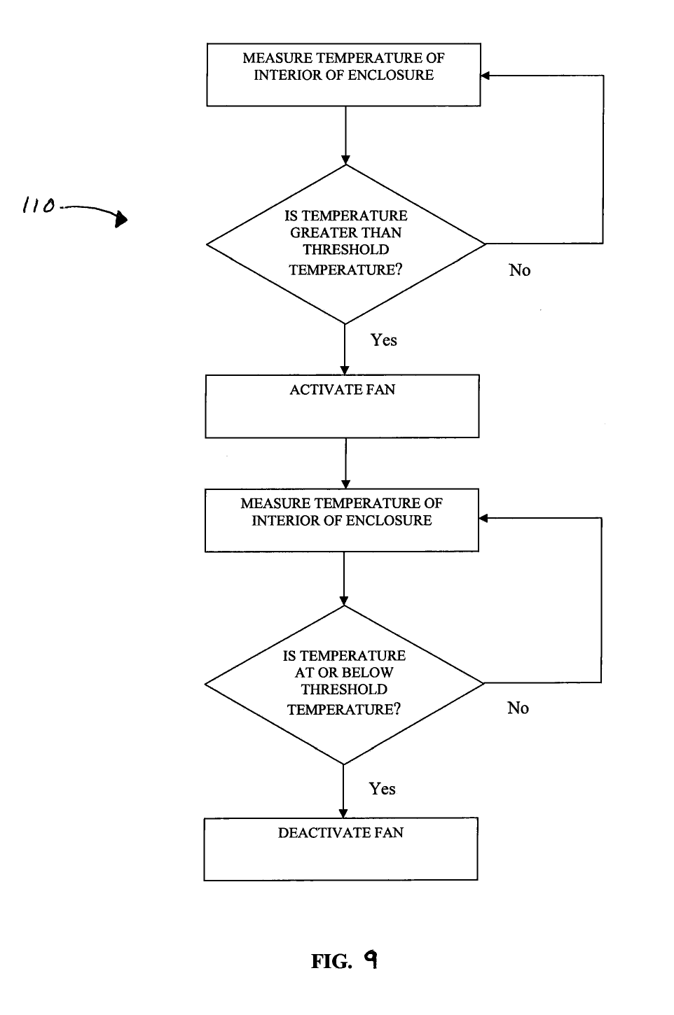

FIG. 9 illustrates a method 110 of ventilating the enclosure 10. The thermostat can measure the temperature in the interior 34 of the enclosure 10. The thermostat can then be programmed to compare the measured temperature to a threshold temperature for the interior 34 of the enclosure 34. If the measured temperature of the interior 34 of the enclosure 10 is greater than the threshold temperature, the thermostat can activate the fan 26 to ventilate the enclosure 10, moving the gravity controlled dampers 52 to an open position as described above. If the measured temperature is not greater than the threshold temperature, then the fan will not be activated and the measurement process will be repeated after a set time interval.

In the case that the fan is activated to increase the internal pressure in the interior 34 of the enclosure 10, the thermostat can again measure the temperature of the interior 34 of the enclosure 10 after a set period of time and compare the measured temperature to the threshold temperature. If the measured temperature is at or below the threshold temperature, then the fan can be deactivated. If the measured temperature is not at or below the threshold temperature, then the fan can continue to run to ventilate the enclosure 10.

In the case that the fan continues to run, the thermostat can again measure the temperature of the interior 34 of the enclosure 10 after a set period of time and compare the measured temperature to the threshold temperature. The fan 26 can continue to run and the thermostat can continue this logic until the temperature of the interior 34 of the enclosure 10 is at or below the threshold temperature, in which case, the fan 26 will be deactivated. This method 110 of ventilating the enclosure 10 can be run continuously in a loop.

The modular design of the enclosure 10 provides several advantages for the enclosure 10. The modular design of the base 20, frame 22, side panels 30, back panel 32, and cover 36 allow for easier transportation of the enclosure into a remote location, such as in an agricultural field. The modular design also allows the back panel 32 to be populated with the electronic equipment with the back panel 32 resting horizontally on the ground or a supporting structure, and then coupled to the frame 22 by lowering the frame on to the back panel 32. The plurality of receptacles 24 in the base 20 allow for different numbers of fans 26 for ventilating the enclosure 10. This allows a user to customize the enclosure 10 by determining the necessary cubic flow requirements for the enclosure 10 based on the heat generated by the electrical equipment that is mounted on the back panel 32 of the enclosure 10. The plurality of receptacles 24 also allows customization to increase the number of fans 26 in the enclosure 10 if the customer later adds more electronic equipment that requires a higher amount of air flow to provide proper cooling. When mounting receptacles 24 are not being used to house a fan 26, gland plates (not shown) can be used to cover the mounting receptacles 24.

The gravity controlled damper system 50 provides for selective ventilation and protects against blowing debris, such as snow, sand, and dust. Even when the gravity controlled dampers 52 move to an open position, the pressure differential between the interior 34 of the enclosure 10 and the outside environment prevents debris or precipitation from entering into the interior 34 of the enclosure 10. This is especially true with snow and dust that can swirl in the wind in any direction.

It will be appreciated by those skilled in the art that while the invention has been described above in connection with particular embodiments and examples, the invention is not necessarily so limited, and that numerous other embodiments, examples, uses, modifications and departures from the embodiments, examples and uses are intended to be encompassed by the claims attached hereto.

1. A modular enclosure for electrical equipment including a first side, a second side, a third side, a fourth side and an interior, the modular enclosure comprising:
a base including at least one mounting receptacle for mounting a first fan;
a frame coupled to the base;
a first side panel, a second side panel, a third side panel, and a fourth side panel coupled to the frame;
a cover coupled to the frame, the cover including an overhang to prevent debris from entering the interior of the enclosure;
a first gravity controlled damper on the first side, the first gravity controlled damper moving to an open position when an internal pressure in the interior of the enclosure increases and moving to a closed position when the internal pressure in the interior of the enclosure decreases; and
a passive air flow passage ventilating the interior of the enclosure when the first gravity controlled damper is in the closed position.

2. The modular enclosure of claim 1, further comprising a back panel coupled to frame in the interior of the enclosure, the back panel adapted to mount the electrical equipment in the enclosure.

3. The modular enclosure of claim 1, wherein the cover further includes an internal mesh screen.

4. The modular enclosure of claim 1, wherein the cover includes the first gravity controlled damper.

5. The modular enclosure of claim 4, wherein the internal pressure in the interior of the enclosure increases by a first fan operating to provide air flow in the interior of the enclosure.

6. The modular enclosure of claim 5, further comprising a thermostat in electrical communication with the first fan, the thermostat activating the first fan when the thermostat senses a temperature in the interior of the enclosure is above a threshold temperature.

7. The modular enclosure of claim 1, wherein the cover includes the passive air flow passage.

8. The modular enclosure of claim 1, further comprising a first hood coupled to the cover, wherein the first gravity controlled damper is coupled to the first hood.

9. The modular enclosure of claim 8, wherein the hood defines a degree of rotation of the first gravity controlled damper moving to the open position.

10. The modular enclosure of claim 8, wherein the first gravity controlled damper includes a proximal end and a distal end, the proximal end is coupled to a hinge that is coupled to the hood, the distal end rotating about the hinge when the first gravity controlled damper moves to the open position.

11. The modular enclosure of claim 8, wherein the passive air flow passage is defined by the passage between an internal surface of the cover and the first hood.

12. The modular enclosure of claim 1, wherein the cover includes a second gravity controlled damper on the second side, a third gravity controlled damper on the third side, and a fourth controlled damper on the fourth side, the second, third, and fourth gravity controlled dampers moving to an open position when the internal pressure in the interior of the enclosure increases.

13. The modular enclosure of claim 1, wherein the base includes a louver.

14. The modular enclosure of claim 13, wherein the louver includes an internal mesh screen.

15. The modular enclosure of claim 13, wherein the louver provides an air intake port and the passive air flow passage provides an air exhaust port.

16. The modular enclosure of claim 1, wherein the base includes a plurality of mounting receptacles for mounting a plurality of fans.

17. The modular enclosure of claim 2, wherein the back panel is comprised of steel and the frame is comprised of aluminum.

18. A method of assembling a ventilated modular enclosure with electrical equipment generating heat, the method comprising:
providing a modular enclosure that includes a base, a frame, side panels, a cover, and a back panel;
installing the base in a desired location;
placing the back panel of the enclosure in a horizontal orientation with respect to the ground;
installing the electrical equipment on the back panel while the back panel is in the horizontal orientation;
coupling the frame to the back panel;
lifting the frame and the back pan& to a vertical orientation;
coupling the side panels and cover to the frame; and
coupling the frame to the base.

19. The method of claim 18, wherein the base has a plurality of mounting receptacles, the method further comprising:
determining the cubic flow requirements for cooling the electrical equipment in the enclosure; and
mounting at least a first fan in one of the plurality of mounting receptacles.

20. The method of claim 18, wherein the back panel is placed on stands when in the horizontal orientation.

21. The method of claim 18, wherein the coupling of the frame to the back panel includes lowering the frame on to the back panel.

22. The method of claim 18, wherein the frame is constructed of aluminum and the back panel is constructed of steel.

23. The method of claim 18, wherein the base includes a louver and the cover includes a gravity controlled damper system and a passive air flow passage.

24. A method for ventilating an enclosure including electrical equipment generating heat, the method comprising:
providing a gravity controlled damper system that includes a first damper, the first damper preventing debris from entering the outdoor enclosure when the first damper is in a closed position and ventilating the enclosure when the first damper is in an open position;
coupling the first damper to the enclosure;
providing a passive air flow passage to the enclosure, the passive air flow passage ventilating the enclosure when the first damper is in the closed position;
sensing a temperature in the interior of the enclosure; and
activating a fan when the temperature in the interior of the enclosure is above a threshold temperature, the fan increasing an internal pressure in the enclosure and moving the first damper to the open position.

25. The method of claim 24, further comprising:
deactivating the fan when the temperature in the interior of the enclosure is at or below the threshold temperature, the first damper moving to the closed position due to a decrease in the internal pressure in the enclosure when the fan is deactivated.

26. The method of claim 24, further comprising:
providing a thermostat in the interior of the enclosure, the thermostat sensing the temperature in the interior of the enclosure.

27. The method of claim 26, wherein the thermostat is configured to activate and deactivate the fan.

28. The method of claim 24, wherein the gravity controlled damper system and passive air flow passage are provided in a cover for the enclosure.

29. The method of claim 28, wherein the cover further includes a first hood and the first damper is coupled to the first hood.

30. The method of claim 29, wherein the passive air flow passageway is defined by the passage between an internal surface of the cover and the first hood.

31. The method of claim 29, wherein the first damper includes a proximal end and a distal end, the proximal end is coupled to a hinge that is coupled to the hood, the distal end rotating about the hinge when the first damper moves to an open position.

32. The method of claim 31, wherein the hood defines an amount of rotation that the first damper can rotate about the hinge.

33. The method of claim 24, wherein the gravity controlled damper system further includes a second damper, a third damper, and a fourth damper, and the first damper being coupled to a first side of the enclosure, the method further comprising:
coupling the second damper to a second side of the enclosure, the second damper functioning the same as the first damper;
coupling the third damper to a third side of the enclosure, the third damper functioning the same as the first damper; and
coupling the fourth damper to a fourth side of the enclosure, the fourth damper functioning the same as the first damper.

34. The method of claim 24, wherein the enclosure includes a louver, the louver providing an air intake port and the passive air flow passage providing an air exhaust port for the enclosure to ventilate the enclosure when the first damper is in the closed position.
